(19) United States
(12) Patent Application Publication
(10) Pub. No.: US 2019/0049512 A1
(43) Pub. Date: Feb. 14, 2019

(54) SYSTEMS AND METHODS FOR SIMPLIFYING INTEGRATION OF LEDs INTO MULTIPLE APPLICATIONS

(71) Applicant: DOMINANT Opto Technologies Sdn Bhd, Melaka, MY (US)

(72) Inventors: Tek Beng LOW, Melaka (MY); Eng Wah TAN, Melaka (MY); Chee Sheng LIM, Melaka (MY)

(73) Assignee: DOMINANT Opto Technologies Sdn Bhd, Melaka (MY)

(21) Appl. No.: 15/681,995

(22) Filed: Aug. 21, 2017

(30) Foreign Application Priority Data
Aug. 9, 2017 (MY) PI 2017702933

(51) Int. Cl. G01R 31/26; G01R 1/04

(52) U.S. Cl. CPC G01R 31/2635; G01R 1/0416

(57) ABSTRACT

A system for simplifying integration of a light emitting diode (LED) into multiple applications includes, an identification module to uniquely identify the light emitting diode (LED) during testing, a storage module for storing testing data of the light emitting diode (LED), a transfer module for transferring testing data of the light emitting diode (LED) down a supply chain to customer end for further processing to achieve a required final color mix, and, a light source molded around a frame, the light emitting diode (LED) being attached and electrically connected to the light source. In use, the testing data includes data relating to at least one characteristic of the light emitting diode (LED). In further use, the LED is a red, green and blue (RGB) LED.

### BACKGROUND OF THE INVENTION

### Field of the Invention

Embodiments of the present invention relate to light emitting diodes (LEDs), and more particularly, to systems and methods for simplifying integration of LEDs into multiple applications.

### Description of the Related Art

As it is well known, among various light emitting diodes (LEDs), Red, green and blue (RGB) light emitting diodes are getting more widely used for illumination nowadays. This is mainly due to their ability to mix and change color depending on the requirement, which becomes very versatile for new illumination designs.

Generally, one of the basic criteria in order to mix and control the resulting color mixture is the basic understanding of the optical and electrical characteristics of each of the colors found within the RGB light source. With this information and subsequent use of pulse width modulation (PWM) while driving the RGB LED, a consistent color control can be achieved.

However, as per current industry practices, there is a clear segregation of functions whereby component manufacturers are responsible for the measurement and characterization of the optical and electrical characteristics of the components. Subsequently, the components LED are then grouped or ‘binned’ into specific groups with clear defined ranges. This binning process eventually leads to cost, inventory management and output issues. Even after the LEDs are binned, the binning information only provides the range and not the exact optical and electrical characteristics of the components. Without exact values, good control over color mix is not possible. As a result, the lighting manufacturers typically would mount each of the RGB LEDs on their modules to realize the lighting applications and then perform optical and electrical measurements to characterize each of the LEDs on the modules.

Conventionally, this is a time consuming and expensive process as the lighting manufacturers may not have the right facilities and expertise to carry out these measurements. In addition, the measurement process itself is more complicated in view of the fact that the RGB LEDs are already mounted on modules that may come in different size and shapes, which can render poor accuracy in measurement and further result in wide spread (non-homogenous) type of final color mix.

Henceforth, because of above-mentioned problems and issues, the final color after Red/Green/Blue light mixture typically will have large variation wherein the color difference can be perceived by human eye (equal or larger than 3 Steps MacAdam Ellipse). Accordingly, there exists a need in the art to simplify this process and to allow lighting manufacturers to integrate RGB LEDs easily into their applications without investment in extra measurement equipment.

### SUMMARY OF THE INVENTION

Embodiments of the present disclosure disclose a system for simplifying integration of a light emitting diode (LED) into multiple applications, including, an identification module to uniquely identify the light emitting diode (LED) during testing, a storage module for storing testing data of the light emitting diode (LED), a transfer module for transferring testing data of the light emitting diode (LED) down a supply chain to customer end for further processing to achieve a required final color mix, and, a light source molded around a frame, the light emitting diode (LED) being attached and electrically connected to the light source. In use, the testing data includes data relating to at least one characteristic of the light emitting diode (LED). In further use, the LED is a red, green and blue (RGB) LED.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a block diagram of a system for simplifying integration of LEDs into multiple applications, in accordance with one embodiment of the present invention;

FIG. 2 illustrates a block diagram of a system for simplifying integration of LEDs into multiple applications, in accordance with second embodiment of the present invention;

FIG. 3 illustrates an ecosystem embodying the system for simplifying integration of LEDs into multiple applications, in accordance with an embodiment of the present invention;

FIG. 4 illustrates an example of data structure associated with each RGB LED package, in accordance with an embodiment of the present invention;

FIG. 5 illustrates an example of final color mix results at end customer application by transforming the LED package data provided, in accordance with an embodiment of the present invention;

FIG. 6 illustrates a block diagram of an application module of the system for simplifying integration of LEDs into multiple applications, in accordance with an embodiment of the present invention; and,

FIG. 7 illustrates a flow diagram of a method for simplifying integration of LEDs into multiple applications, in accordance with an embodiment of the present invention.

While the present systems and methods have been described herein by way of example for several embodiments and illustrative drawings, those skilled in the art will recognize that the multiple embodiments disclosed hereinbelow are not limited to the embodiments or drawings described. It should be understood, that the drawings and detailed description thereto are not intended to limit embodiments to the particular form disclosed. Rather, the intention is to cover all modifications, equivalents and alternatives falling within the spirit and scope of the invention as defined by the appended claims. Any headings used herein are for organizational purposes only and are not meant to limit the scope of the description or the claims. As used herein, the word “can” and “may” is used in a permissive sense (i.e., meaning having the potential to), rather than the mandatory sense (i.e., meaning must). Similarly, the words “include”, “including”, and “includes” mean including, but not limited to.

### DETAILED DESCRIPTION

Various embodiments of the present invention relate to systems and methods for simplifying integration of LEDs into multiple applications.

According to multiple embodiments of the present invention, the systems and methods as disclosed herein are aimed at eliminating the needs of lighting manufacturers from performing optical testing of RGB LED piece by piece after LED surface mounting, thereby saving capital investment and manufacturing cycle time. In addition, the solutions provided by the present invention enhance final color mix accuracy because every piece of the LED component is measured by LED manufacture using precision optical measurement equipment under the same conditions.

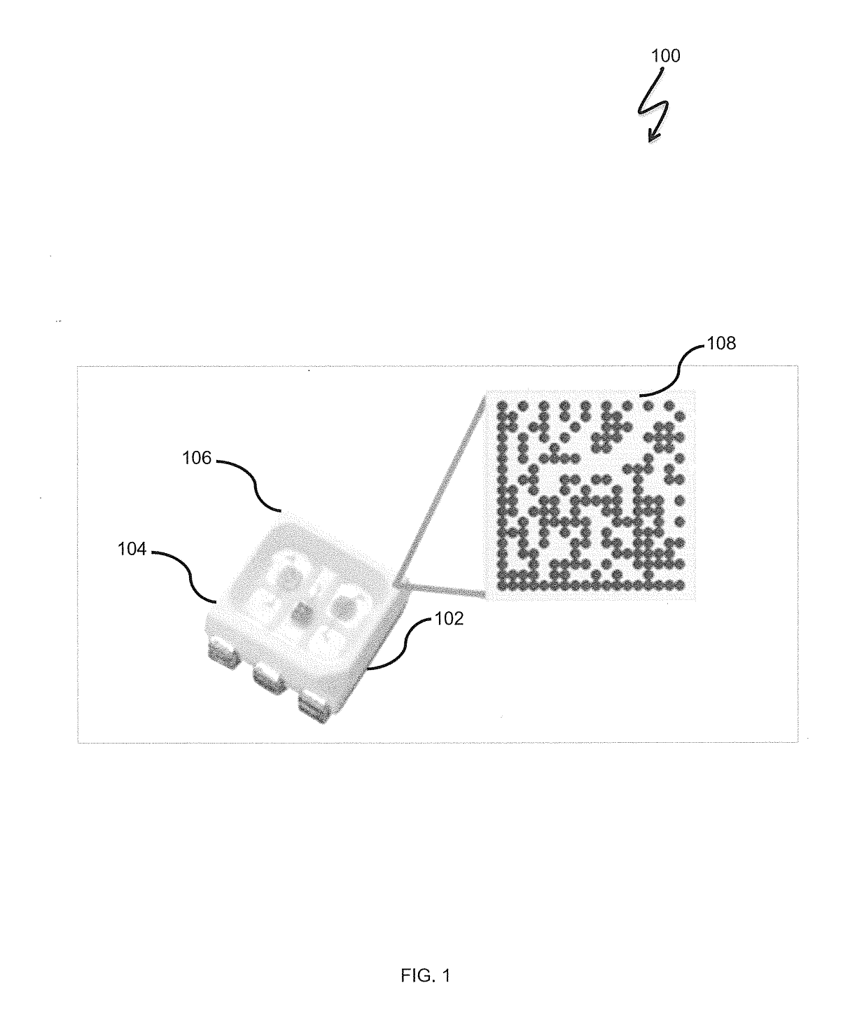

FIG. 1 illustrates a block diagram of a system 100 for simplifying integration of LEDs into multiple applications. In accordance with an embodiment of the present invention, the system 100 for simplifying integration of a light emitting diode (LED) 102 into multiple applications includes, an identification module to uniquely identify the light emitting diode (LED) 102 during testing, a storage module for storing testing data of the light emitting diode (LED) 102, a transfer module for transferring testing data of the light emitting diode (LED) 102 down a supply chain to customer end for further processing to achieve a required final color mix, and, a light source 104 molded around a frame, the light emitting diode (LED) 102 being attached and electrically connected to the light source 104. In use, the testing data includes data relating to at least one characteristic of the light emitting diode (LED) 102. In further use, the LED 102 is a red, green and blue (RGB) LED.

In accordance with an embodiment of the present invention, the light source 104 is a plastic light source insert-molded around a copper lead-frame. In use, the light source 104 further includes a top surface 106 for displaying an identification code 108. In further use, the identification code 108 is selected from a group including a two-dimensional (2-D) matrix barcode, a combination of a plurality of unique serial numbers and any other code generated by using at least one industry standard. Generally, the identification code 108 is laser-marked on the top surface 106 of the light source 104. Those of ordinary skills in the art will appreciate that the unique identification code 108 is printed, laser-marked, etched or stamped on each of the RGB LED package 102 in a manner such that the marking is legible by some means of machine vision. It would be further appreciated that the light source as mentioned herein may refer to a LED, a RGB LED, and the like.

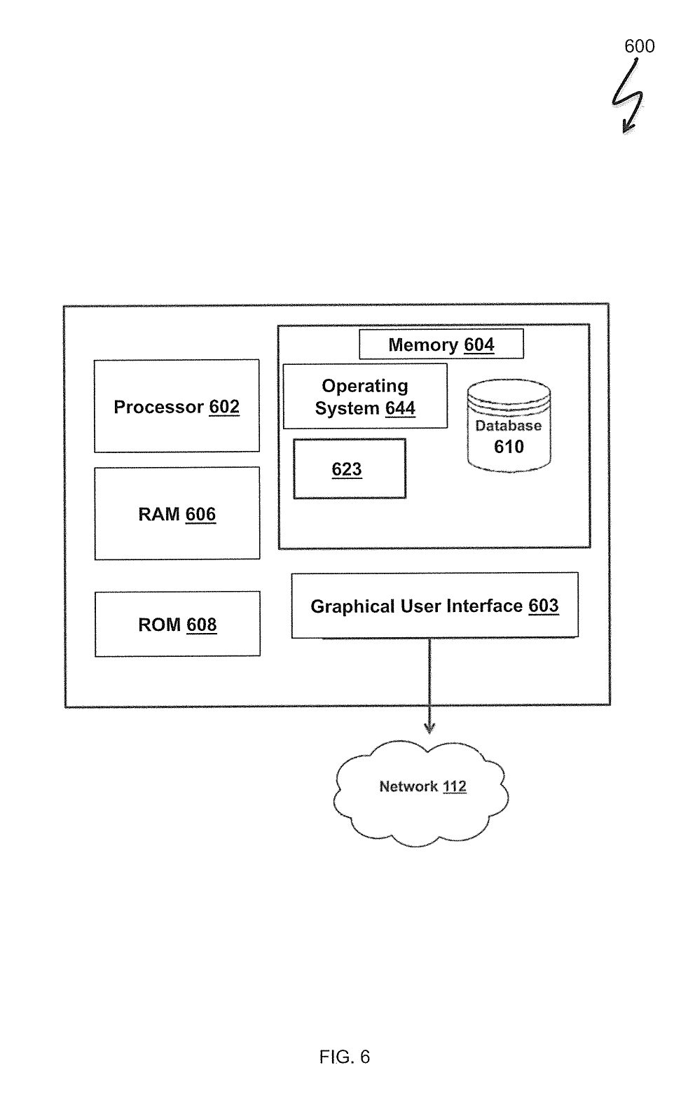

In accordance with an embodiment of the present invention, the system 100 further includes an application module 600 having, a processor 602 configured to trace and match the testing data, and, a memory 604 to store the information corresponding to the testing data in a database. The application module 600 is discussed with reference to FIG. 6, as explained hereinbelow.

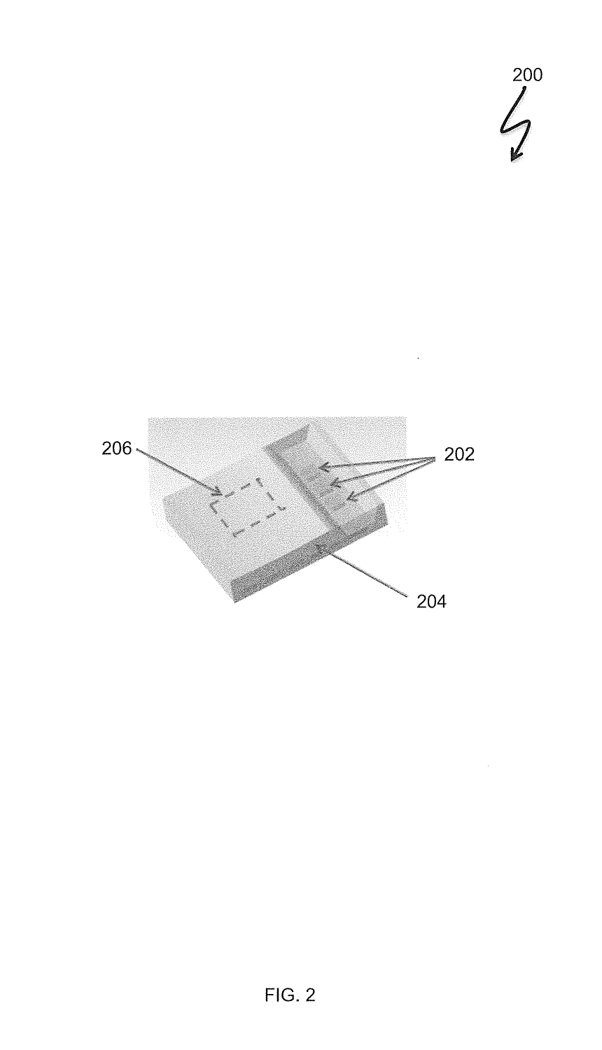

FIG. 2 illustrates a block diagram of a system 200 for simplifying integration of LEDs into multiple applications. In accordance with second embodiment of the present invention, the system 200 for simplifying integration of a light emitting diode (LED) 202 into multiple applications includes, an identification module to uniquely identify the light emitting diode (LED) 202 during testing, a storage module for storing testing data of the light emitting diode (LED) 202, a transfer module for transferring testing data of the light emitting diode (LED) 202 down a supply chain to customer end for further processing to achieve a required final color mix, and, a light source 204 for packaging the light emitting diode (LED) 202. In use, the testing data includes data relating to at least one characteristic of the light emitting diode (LED) 202. In further use, the LED 202 is a red, green and blue (RGB) LED.

In accordance with an embodiment of the present invention, the light source 204 is a plastic light source. In use, the system further includes an identification chip 206 having an identification memory. Generally, the identification chip is a radio frequency identification (RFID) chip or an integrated circuit (IC) chip. In addition, the light source further includes a top surface for displaying the identification code, as explained hereinabove.

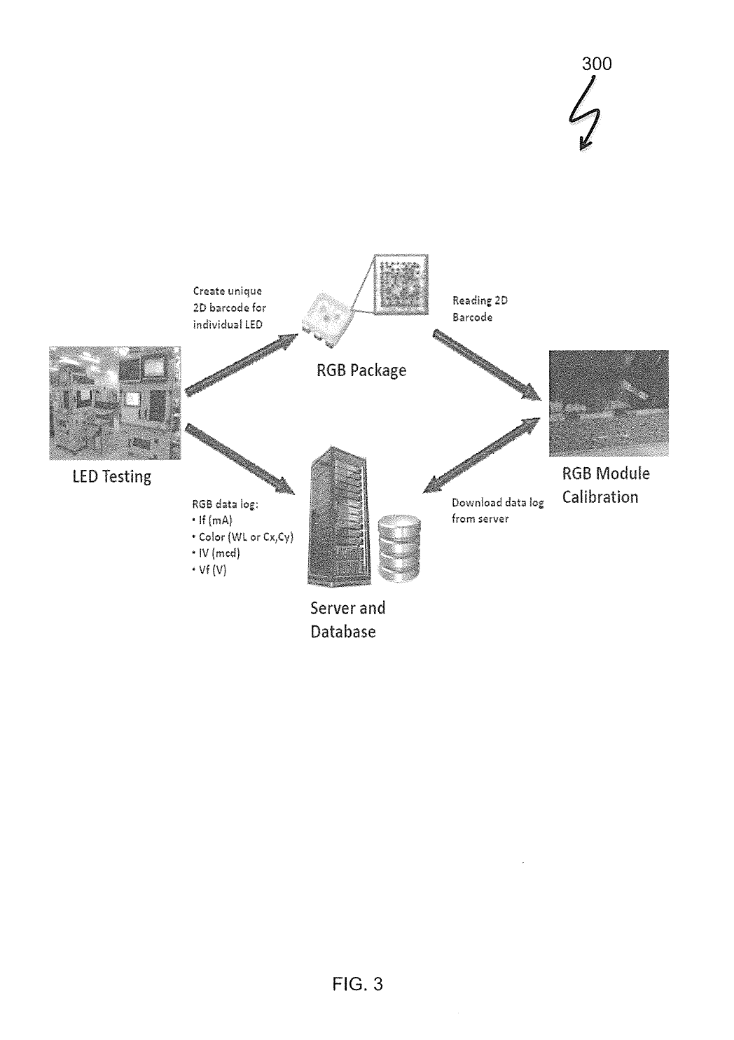

Those of ordinary skills in the art will appreciate that the second embodiment of the present invention is aimed at serving the same identification purpose as that of the first embodiment but by way of sensing or programming. FIG. 3 illustrates an ecosystem 300 embodying the system for simplifying integration of LEDs into multiple applications, in accordance with an embodiment of the present invention. It will be further appreciated that in accordance with multiple embodiments of the present invention, the transfer module is configured for transferring the testing data of the light emitting diode (LED) to a customer end for the further processing to achieve the required final color mix.

In accordance with an embodiment of the present invention, at the process point where the measurement and characterization of the optical and electrical data of the LED component is done, the unique identification is also read and associated to the optical and electrical data measured. Subsequently, with this process, every single component with its unique identification will have a corresponding set of optical and electrical data, wherein such data can then be stored digitally and designed for easy retrieval later.

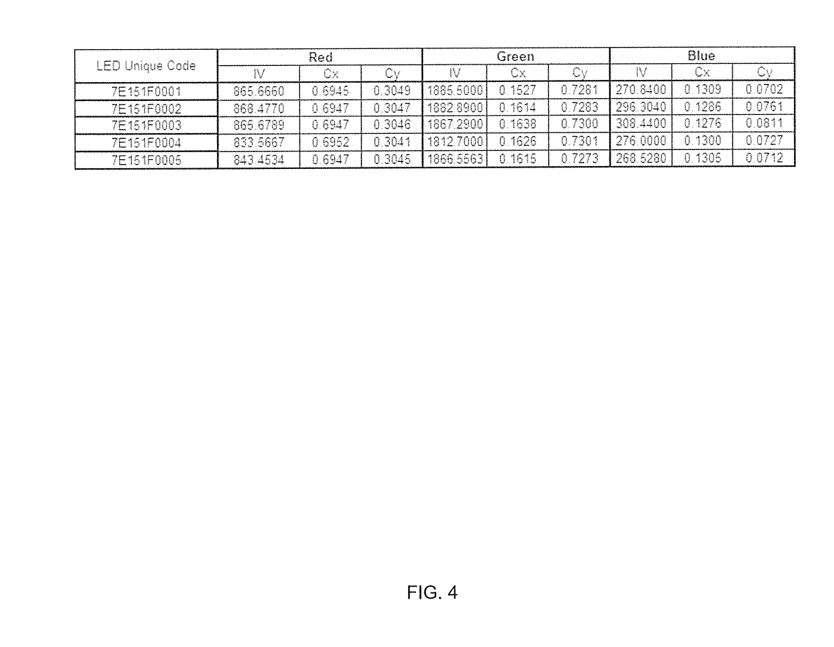

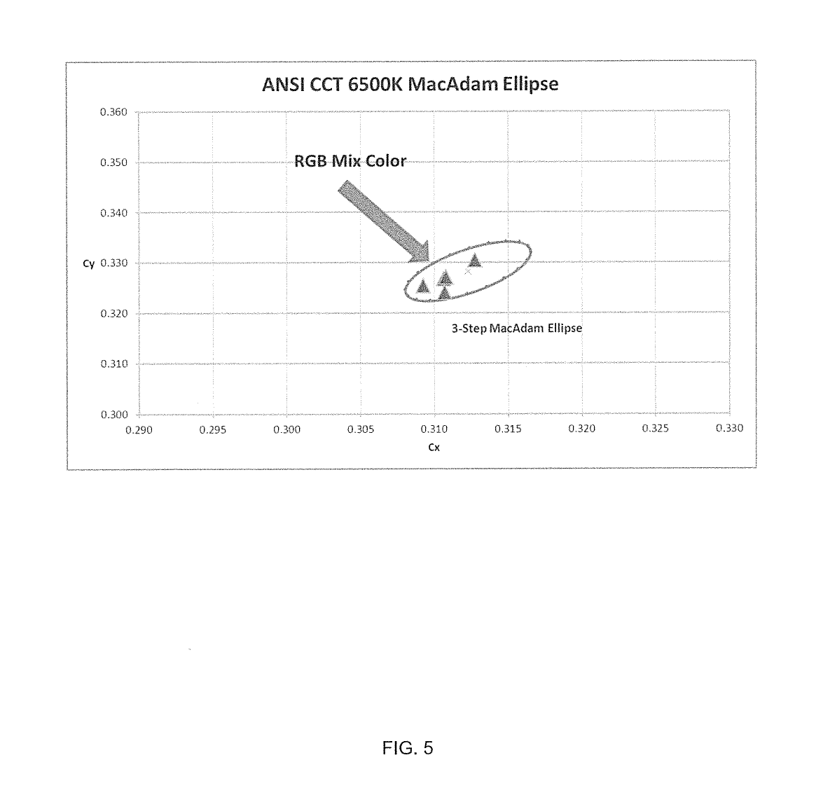

Generally, further down the supply chain, the lighting manufacturer will mount the RGB LEDs onto their modules as part of their standard process. In use, as for the control and to realize the color mixing feature, the lighting manufacturer can easily assess the optical and electrical data of each RGB LED by reading the unique identification code on each of the LED components. The unique identification code can then be used to trace and match against the data which was stored earlier. Subsequently, the data, as illustrated in FIG. 4 can be use by the color mixing algorithm to achieve final color target illustrated in FIG. 5. As illustrated in FIG. 5, this provides the capability to achieve tight color control of within 3 Steps MacAdam.

FIG. 6 illustrates a block diagram of the application module 600 of the system 100 for simplifying integration of LEDs into multiple applications. In accordance with an embodiment of the present invention, the application module 600 may be similar to any available computing device, such as a personal computer (e.g., a desktop computer), server, laptop computer, notebook, tablet, smartphone, etc. Moreover, the application module 600 may embody the other modules discussed above for performing methods and executing instructions as described hereinbelow. The one or more modules explained above may be implemented with one or more processors and one or more storage units (e.g., databases 610, RAM 606, ROM 608, and other computer-readable media), one or more application specific integrated circuits (ASICs), and/or other hardware components.

In use, the processor 602 is capable of controlling operations of the application module 600 and its associated components, including RAM 606, ROM 608, the graphical user interface 603, and the memory 604. The memory 604 may be any computer readable medium for storing computer executable instructions (e.g., software). The instructions stored within memory 604 may enable the application module 600 to perform various functions. For example, memory 604 may store software used by the application module 600, such as an operating system 644 and application programs 623, and may include the database 610. The graphical user interface 603 allows the application module 600 to connect to and communicate with the network 112. The network 112 may be any type of network, including a local area network (LAN) and/or a wide area network (WAN), such as the Internet, a cellular network, or satellite network.

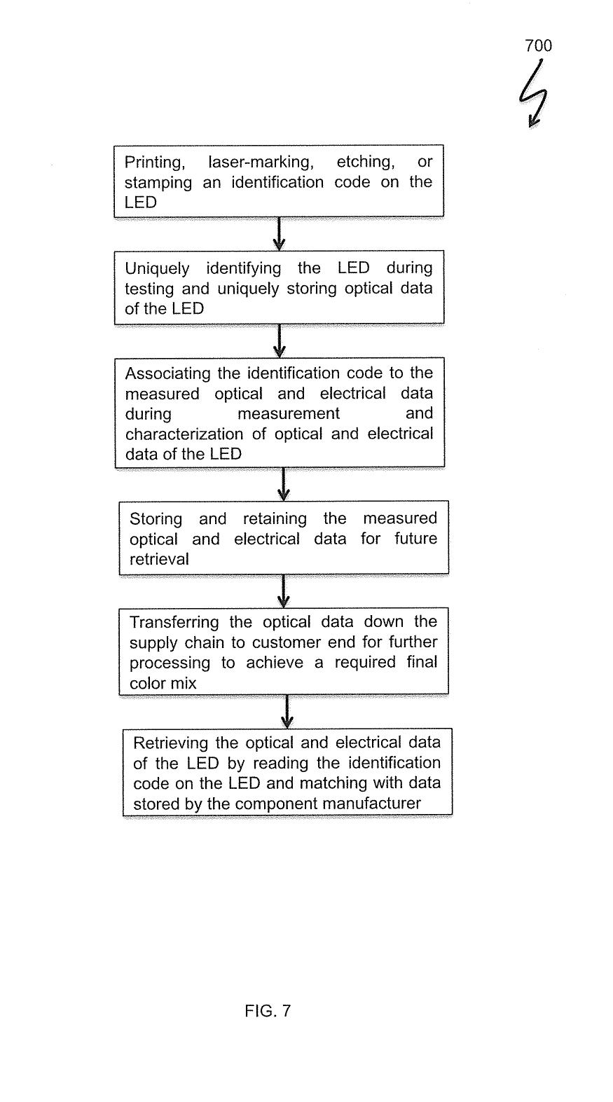

FIG. 7 illustrates a flow diagram of a method 700 for simplifying integration of LEDs into multiple applications. In accordance with an embodiment of the present invention, the method 700 for simplifying integration of a light emitting diode (LED) into multiple applications includes the steps of, uniquely identifying the LED during testing, uniquely storing testing data of the LED, and, transferring the testing data down the supply chain to customer end for further processing to achieve a required final color mix. In use, the testing data comprises data relating to at least one characteristic of the light emitting diode (LED).

In accordance with an embodiment of the present invention, the method further includes the step of printing, laser-marking, etching, or stamping an identification code on the LED. In use, the method further includes the steps of, associating the identification code to the measured optical and electrical data during measurement and characterization of optical and electrical data of the LED, and, storing and retaining the measured optical and electrical data for future retrieval.

In accordance with an embodiment of the present invention, the method further includes the step of retrieving the optical and electrical data of the LED by reading the identification code on the LED and matching with data stored by the component manufacturer.

In accordance with an embodiment of the present invention, the step of transferring the testing data for further processing to achieve the required final color mix includes transferring the testing data to a customer end.

Therefore, as may be seen, various embodiments of the present invention disclose systems and methods for simplifying integration of LEDs into multiple applications, which provides creation of a new ecosystem wherein each piece of LED is uniquely identified during testing, and subsequently, the testing data of each piece of LED is uniquely stored. Consequently, this testing data is transferred down the supply chain to customer end for further processing to achieve the required final color mix.

In addition to the above, during the measurement and characterization of the optical and electrical of the LED components, the unique identification code is associated to the optical and electrical data measured, and such data is then stored and retained for future retrieval. Accordingly, when the LED component subsequently moves down the supply chain to the lighting manufacturers, the optical and electrical data can then be easily retrieved by reading the unique identification code on each of the LED components and matching such unique identification code with the data stored by the LED component manufacturers.

Accordingly, while there has been shown and described the preferred embodiment of the invention is to be appreciated that the invention may be embodied otherwise than is herein specifically shown and described and, within said embodiment, certain changes may be made in the form and arrangement of the parts without departing from the underlying ideas or principles of this invention within the scope of the claims appended herewith.

1. A system for simplifying integration of a light emitting diode (LED) into multiple applications, said system comprising:
an identification module to uniquely identify said light emitting diode (LED) during testing;
a storage module for storing testing data of said light emitting diode (LED);
a transfer module for transferring testing data of said light emitting diode (LED) for further processing to achieve a required final color mix; and,
a light source molded around a frame, said light emitting diode (LED) being attached and electrically connected to said light source,
wherein said testing data comprises data relating to at least one characteristic of said light emitting diode (LED).

2. The system as claimed in claim 1, wherein said light source is a plastic light source insert-molded around a copper lead-frame.

3. The system as claimed in claim 1, wherein said LED is a red, green and blue (RGB) LED.

4. The system as claimed in claim 1, wherein said light source further comprises a top surface for displaying an identification code.

5. The system as claimed in claim 4, wherein said identification code is selected from a group comprising a two-dimensional (2-D) matrix barcode, a combination of a plurality of unique serial numbers and any other code generated by using at least one industry standard.

6. The system as claimed in claim 4, wherein said identification code is laser-marked on said top surface of said light source.

7. The system as claimed in claim 1, wherein said system further comprises an application module having:
a processor configured to trace and match said testing data; and,
a memory to store said information corresponding to said testing data in a database.

8. The system as claimed in claim 1, wherein said transfer module is configured for transferring said testing data of said light emitting diode (LED) to a customer end for said further processing to achieve said required final color mix.

9. A system for simplifying integration of a light emitting diode (LED) into multiple applications, said system comprising:
an identification module to uniquely identify said light emitting diode (LED) during testing;
a storage module for storing testing data of said light emitting diode (LED);
a transfer module for transferring testing data of said light emitting diode (LED) for further processing to achieve a required final color mix; and,
a light source for packaging said light emitting diode (LED),
wherein said testing data comprises data relating to at least one characteristic of said light emitting diode (LED).

10. The system as claimed in claim 9, wherein said light source is a plastic light source.

11. The system as claimed in claim 9, wherein said system further comprises an identification chip having an identification memory.

12. The system as claimed in claim 11, wherein said identification chip is a radio frequency identification (RFID) chip.

13. The system as claimed in claim 11, wherein said identification chip is an integrated circuit (IC) chip.

14. The system as claimed in claim 9, wherein said LED is a red, green and blue (RGB) LED.

15. The system as claimed in claim 9, wherein said light source further comprises a top surface for displaying an identification code.

16. The system as claimed in claim 15, wherein said identification code is selected from a group comprising a two-dimensional (2-D) matrix barcode, a combination of a plurality of unique serial numbers and any other code generated by using at least one industry standard.

17. The system as claimed in claim 15, wherein said identification code is laser-marked on said top surface of said light source.

18. The system as claimed in claim 9, wherein said system further comprises an application module having:
a processor configured to trace and match said testing data; and,
a memory to store said information corresponding to said testing data in a database.

19. The system as claimed in claim 9, wherein said transfer module is configured for transferring said testing data of said light emitting diode (LED) to a customer end for said further processing to achieve said required final color mix.

20. A method for simplifying integration of a light emitting diode (LED) into multiple applications, said method comprising the steps of:
uniquely identifying said LED during testing;
uniquely storing testing data of said LED; and,
transferring said testing data for further processing to achieve a required final color mix,
wherein said testing data comprises data relating to at least one characteristic of said light emitting diode (LED).

21. The method as claimed in claim 20, wherein said method further comprises the step of printing, laser-marking, etching, or stamping an identification code on said LED.

22. The method as claimed in claim 20, wherein said method further comprises the steps of:
associating said identification code to the measured optical and electrical data during measurement and characterization of optical and electrical data of said LED; and,
storing and retaining said measured optical and electrical data for future retrieval.

23. The method as claimed in claim 20, wherein said method further comprises the step of retrieving said optical and electrical data of said LED by reading said identification code on said LED and matching with data stored by a component manufacturer.

24. The method as claimed in claim 20, wherein said LED is a red, green and blue (RGB) LED.

25. The method as claimed in claim 20, wherein said identification code is selected from a group comprising a two-dimensional (2-D) matrix barcode, a combination of a plurality of unique serial numbers and any other code generated by using at least one industry standard.

26. The method as claimed in claim 20, wherein said step of transferring said testing data for further processing to achieve said required final color mix comprises transferring said testing data to a customer end.
